(19) United States
(12) Patent Application Publication
(10) Pub. No.: US 2015/0241465 A1
(43) Pub. Date: Aug. 27, 2015

(54) PIEZORESISTIVE MEMS SENSOR

(71) Applicant: Murata Manufacturing Co., Ltd., Nagaokakyo-shi (JP)

(72) Inventor: Takahiro KONISHI, Nagaokakyo-shi (JP)

(21) Appl. No.: 14/712,004

(22) Filed: May 14, 2015

Related U.S. Application Data
(63) Continuation of application No. PCT/JP2013/082545, filed on Dec. 4, 2013.

(30) Foreign Application Priority Data
Dec. 6, 2012 (JP) 2012-267348

(51) Int. Cl. G01P 15/12; B81B 3/00; G01L 9/00

(52) U.S. Cl. CPC G01P 15/123; G01L 9/0052; B81B 3/0072; B81B 2201/0264; B81B 2201/0235

(57) ABSTRACT

A pressure sensor includes a SOI substrate that includes a Si substrate, a SiO₂ layer, and a surface Si film. An opening portion is formed in the Si substrate through etching, and a displacement portion having a membrane structure is defined by the surface Si film and the SiO₂ layer in this area. A piezoresistive element is provided in the displacement portion. The displacement portion bends in response to a pressure to be detected and a resistance value of the piezoresistive element changes in response thereto. A thickness of the membrane-structure displacement portion is not less than about 1 μm and not greater than about 10 μm, and a depth of a peak of an impurity concentration of the piezoresistive element is greater than about 0.5 μm and at a position less than about ½ of the depth of the thickness of the displacement portion.

### BACKGROUND OF THE INVENTION

1. Field of the Invention

The present invention relates to MEMS devices preferably used as sensors, and particularly relates to piezoresistive MEMS sensors that detect pressure, acceleration, or the like based on changes in a resistance value of a piezoresistive element.

2. Description of the Related Art

Japanese Unexamined Patent Application Publication No. 2006-30158, for example, discloses a MEMS (Micro Electro Mechanical Systems)-based sensor. Japanese Unexamined Patent Application Publication No. 2006-30158 describes a semiconductor pressure sensor constituted by an SOI substrate on which a diaphragm is formed and four piezoresistive elements formed on the SOI substrate.

In order to increase the sensitivity thereof, a piezoresistive element in a piezoresistive sensor is formed in an ultra-shallow position near a surface of Si that forms a displacement portion, such as a membrane or a beam. There are also cases where a protective film, a shielding film, or the like is formed on the surface of the Si. Although not mentioned in any prior art documents, a depth of the piezoresistive element (a depth of a peak of an impurity concentration) is normally no greater than 0.3 μm from the surface of the Si, excluding the protective film and so on.

Although the depth of the piezoresistive element (the depth of the peak of the impurity concentration) being no greater than 0.3 μm from the surface of the Si is useful in terms of improving the sensitivity of the sensor, there is a problem in that variations in a thickness of the displacement portion, such as a membrane or a beam, will affect the sensor sensitivity and cause large variations therein. This is because stress arising at a surface of the displacement portion is inversely proportional to the square of the thickness thereof. A relationship between the sensor sensitivity and variations thereof will be described later.

In applications where variations in the sensor sensitivity are viewed as important, a process for individually correcting such variations becomes necessary, which causes an increase in costs.

### SUMMARY OF THE INVENTION

Preferred embodiments of the present invention provide a piezoresistive MEMS sensor that reduces the influence that variations in a thickness of a displacement portion in which a piezoresistive element is provided have on fluctuations in a sensitivity of the sensor.

A preferred embodiment of the present invention provides a piezoresistive MEMS sensor, including a displacement portion made of Si having a thickness of not less than about 1 μm that is configured to be displaced according to a detection amount, a piezoresistive element defined by an impurity diffused material within the displacement portion, and the piezoresistive element having an impurity concentration peak at a position deeper than about 0.5 μm from a surface of the displacement portion and shallower than about ½ of a thickness dimension of the displacement portion.

It is preferable that the thickness of the displacement portion be not less than about 1 μm and not greater than about 10 μm, for example.

It is preferable that a Si oxide film or a Si nitride film is provided on a surface of the displacement portion.

According to various preferred embodiments of the present invention, the influence that variations in a thickness of a displacement portion such as a membrane or a beam have on a sensitivity of a sensor is significantly reduced or prevented, and thus a piezoresistive MEMS sensor having a desired sensor sensitivity is greatly provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a diagram illustrating a positional relationship of a piezoresistive element 11 with respect to a displacement portion (active layer) 12, such as a membrane or a beam.

FIG. 2A is a diagram illustrating a qualitative relationship between a thickness dimension ts of the displacement portion 12 and a maximum stress σ exerted on the displacement portion 12. FIG. 2B is a diagram illustrating a qualitative relationship between the thickness dimension ts of the displacement portion 12 and a stress efficiency E at a position of a depth of the piezoresistive element 11 (a depth of a peak of an impurity concentration). FIG. 2C is a diagram illustrating a qualitative relationship between the thickness dimension ts of the displacement portion 12 and a sensitivity S.

FIG. 3 is a diagram illustrating a result of determining a relationship between the depth of the piezoresistive element 11 (the depth of the peak of the impurity concentration) and the sensitivity through the FEM, using the thickness dimension of the displacement portion as a parameter.

FIG. 4 is a diagram illustrating an example of an impurity concentration profile in the piezoresistive element 11.

FIG. 5 is a cross-sectional view of a pressure sensor according to Working Example 1.

FIG. 6A, FIG. 6B, and FIG. 6C are cross-sectional views illustrating a process for manufacturing the pressure sensor illustrated in FIG. 5.

FIG. 7 is a cross-sectional view of a pressure sensor according to Working Example 2.

FIG. 8A, FIG. 8B, FIG. 8C, and FIG. 8D are cross-sectional views illustrating a process for manufacturing the pressure sensor illustrated in FIG. 7.

FIG. 9 is a cross-sectional view of an accelerometer according to Working Example 3.

FIG. 10A, FIG. 10B, and FIG. 10C are cross-sectional views illustrating a process for manufacturing the accelerometer illustrated in FIG. 9.

### DETAILED DESCRIPTION OF THE PREFERRED EMBODIMENTS

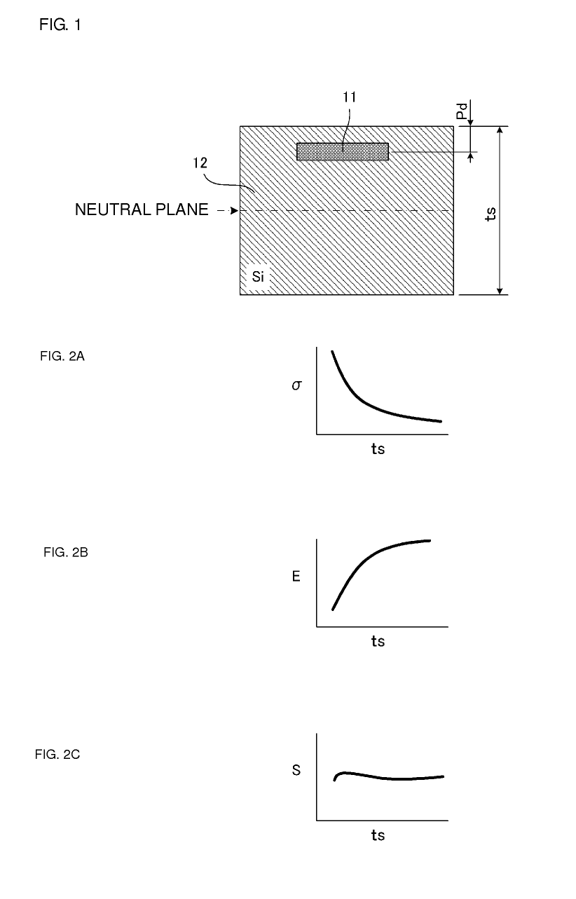

FIG. 1 is a diagram illustrating a positional relationship of a piezoresistive element 11 with respect to a displacement portion (active layer) 12, such as a membrane or a beam. The displacement portion 12 preferably includes a Si layer. The piezoresistive element 11 is made of an impurity diffused material. A thickness dimension of the displacement portion is represented by ts, and a depth of a peak of the impurity concentration of the piezoresistive element 11 is represented by Pd.

FIG. 2A is a diagram illustrating a qualitative relationship between the thickness dimension ts of the displacement portion 12 and a maximum stress σ exerted on the displacement portion 12. Expressing this relationship as a formula results in the following.

σ=(1/ts²)α

Here, α is a coefficient determined by a dimension of the displacement portion 12.

FIG. 2B is a diagram illustrating a qualitative relationship between the thickness dimension ts of the displacement portion 12 and a stress efficiency E at a position of a depth of the piezoresistive element 11 (the depth of the peak of the impurity concentration). Expressing this relationship as a formula results in the following.

E=(ts/2−Pd)/(ts/2)=(ts−2Pd)/ts

FIG. 2C is a diagram illustrating a qualitative relationship between the thickness dimension ts of the displacement portion 12 and a sensitivity S. Expressing this relationship as a formula results in the following.

S=σ×E=α(ts−2Pd)/ts³

Here, when maximum and minimum thicknesses of the thickness dimension of the displacement portion 12 are represented by tsₘₐₓ and tsₘᵢₙ, respectively, sensitivities Smax and Smin at the respective thicknesses are as follows.

Smax=α(tsₘₐₓ−2Pd)/tsₘₐₓ³

Smin=α(tsₘᵢₙ−2Pd)/tsₘᵢₙ³

When the value of the depth of the piezoresistive element (the depth of the peak of the impurity concentration) Pd is determined so that Smax=Smin, the influence that variations in the thickness dimension of the displacement portion have on the sensitivity will be at its lowest.

Smax=Smin

α(tsₘₐₓ−2Pd)/tsₘₐₓ³=α(tsₘᵢₙ−2Pd)/tsₘᵢₙ³

Pd=tsₘₐₓ tsₘᵢₙ(tsₘₐₓ²−tsₘᵢₙ²)/{2(tsₘₐₓ³−tsₘᵢₙ³)}

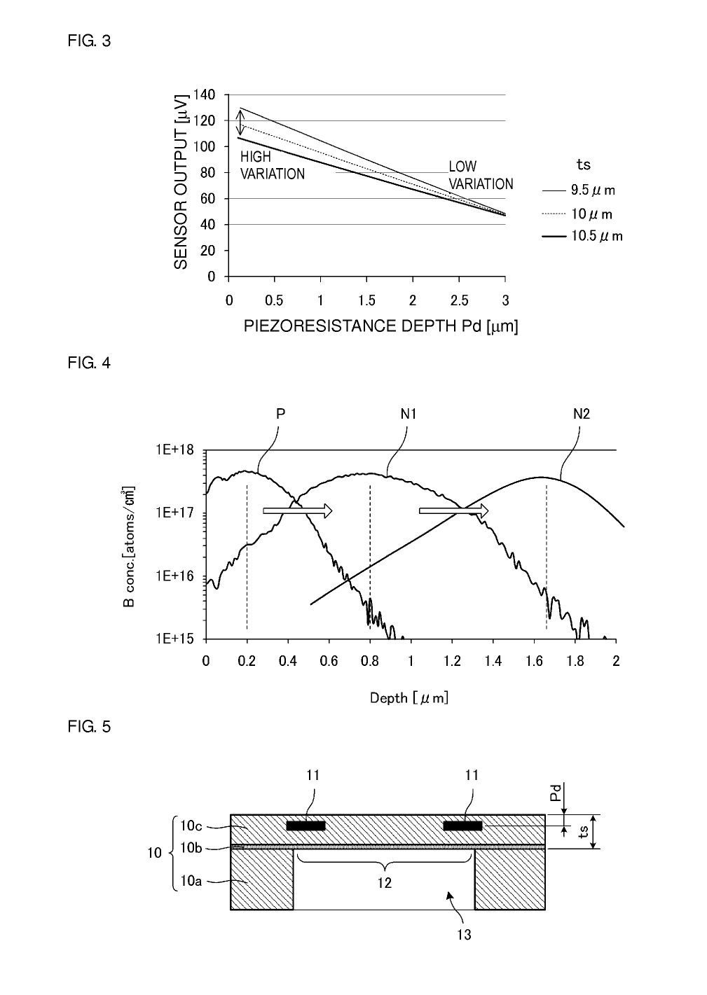

FIG. 3 is a diagram illustrating a result of determining a relationship between the depth of the piezoresistive element 11 (the depth of the peak of the impurity concentration) and the sensitivity through the FEM, using the thickness dimension of the displacement portion as a parameter. The sensitivity is at its lowest when the depth of the piezoresistive element 11 is a depth that is about ½ of the thickness dimension of the displacement portion (a neutral plane), and the sensitivity increases as the depth of the piezoresistive element 11 decreases. A ratio of sensitivity variation relative to variation in the thickness dimension of the displacement portion increases as the depth of the piezoresistive element 11 decreases.

In the case of a conventional structure, when the thickness of the displacement portion, such as a membrane or a beam, is set to 10 μm and that thickness is created through a normal process, variations of ±0.5 μm are produced. In the conventional structure, a piezoresistance is formed on the surface of the displacement portion, and thus the sensor sensitivity varies under the influence equivalent to the square of the thickness of the displacement portion. That is, the sensitivity variation is ±10% or more.

As opposed to this, according to the structure of a preferred embodiment of the present invention, in the case where the thickness of the displacement portion is about 10 μm and the piezoresistance is formed and configured so that the position of the peak of the impurity concentration thereof is at a depth of about 0.5 μm from the surface of the displacement portion, the sensitivity is less susceptible to the influence of variations in the thickness of the displacement portion than in the conventional structure. As illustrated in FIG. 3, according to the structure of a preferred embodiment of the present invention, the sensitivity variation will be about ±6% in the case where the thickness dimension of the displacement portion 12 is about 10±0.5 μm (tsₘₐₓ=10.5 μm, tsₘᵢₙ=9.5 μm) and when the depth Pd of the piezoresistive element is about 2 μm, for example.

As illustrated in FIG. 3, the sensitivity variation drops with respect to variation in the depth of the piezoresistive element as the thickness of the displacement portion 12 increases, but the sensitivity also decreases as the thickness of the displacement portion 12 increases. It is necessary to increase the detection sensitivity of a sensor in order to miniaturize the sensor. As such, there is a correlation between the sensor sensitivity and the thickness of the displacement portion 12, and it is necessary to reduce the thickness of the displacement portion 12 in order to increase the sensitivity. In typical MEMS sensors used in civilian applications, the thickness of the membrane or beam is not greater than about 10 μm. Accordingly, it is preferable for thickness dimension of the displacement portion 12 to be not greater than about 10 μm, for example.

FIG. 4 is a diagram illustrating an example of an impurity concentration profile in the piezoresistive element 11. The horizontal axis represents depth and the vertical axis represents a carrier concentration. In a conventional piezoresistive MEMS sensor, the depth of the peak of the impurity concentration is 0.2 μm, as indicated by a profile P; however, according to a preferred embodiment of the present invention, the depth of the peak of the impurity concentration preferably is about 0.8 μm, about 1.65 μm, and so on, as indicated by profiles N1 and N2, for example.

### WORKING EXAMPLES

### Working Example 1

FIG. 5 is a cross-sectional view of a pressure sensor according to Working Example 1. This pressure sensor is constituted by a SOI substrate that preferably is a Si substrate 10a, a SiO₂ layer 10b, and a surface Si film 10c. An opening portion 13 is formed in the Si substrate 10a preferably through etching, and the displacement portion 12 having a membrane structure is defined by the surface Si film 10c and the SiO₂ layer 10b in this area. The piezoresistive element 11 is formed in the displacement portion 12 preferably through ion injection. The displacement portion 12 bends in response to a pressure to be detected and a resistance value of the piezoresistive element changes in response thereto.

Here, the thickness dimension is of the membrane-structure displacement portion 12 preferably is not less than about 1 μm and not greater than about 10 μm, and the position (depth) Pd of the peak of the impurity concentration of the piezoresistive element 11 is greater than about 0.5 μm and at a position less than about ½ of the depth of the thickness dimension of the displacement portion 12, for example.

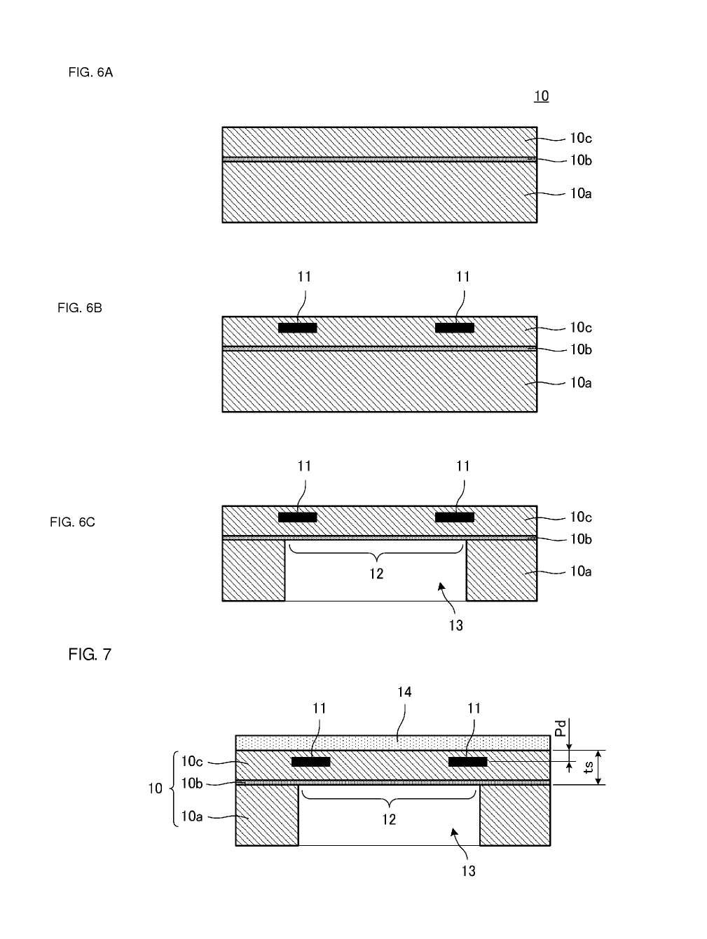

FIG. 6A, FIG. 6B, and FIG. 6C are cross-sectional views illustrating a non-limiting example of a process for manufacturing the pressure sensor illustrated in FIG. 5. First, as illustrated in FIG. 6A, an SOI substrate 10 formed of the Si substrate 10a, the SiO₂ layer 10b, and the surface Si film 10c is prepared. Next, as illustrated in FIG. 6B, the piezoresistive element 11 is formed through ion injection from the surface Si film 10c. Then, as illustrated in FIG. 6C, the opening portion is formed in the Si substrate 10a through etching. The membrane-structure displacement portion 12 is formed as a result.

### Working Example 2

FIG. 7 is a cross-sectional view of a pressure sensor according to Working Example 2. In this example, a protective film 14 is formed on the surface of the Si film 10c on which the piezoresistive element 11 is formed. The rest of the configuration is preferably the same as in the pressure sensor illustrated in FIG. 5.

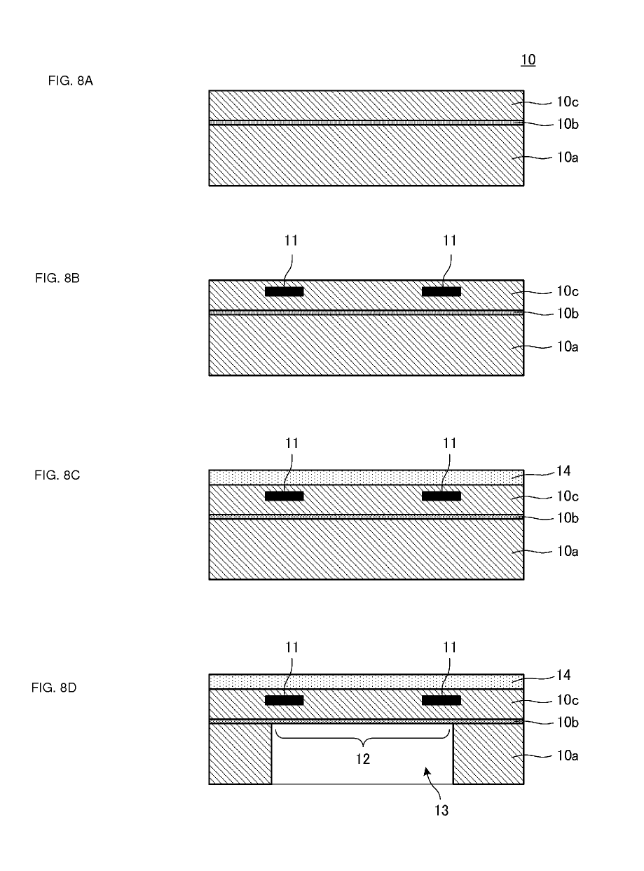

FIG. 8A, FIG. 8B, FIG. 8C, and FIG. 8D are cross-sectional views illustrating a non-limiting example of a process for manufacturing the pressure sensor illustrated in FIG. 7. First, as illustrated in FIG. 8A, an SOI substrate 10 formed of the Si substrate 10a, the SiO₂ layer 10b, and the surface Si film 10c is prepared. Next, as illustrated in FIG. 8B, the piezoresistive element 11 is formed through ion injection from the surface Si film 10c. Then, as illustrated in FIG. 8C, the protective film 14 constituted by a Si oxide film or a Si nitride film is formed on the surface through thermal oxidization or CVD. Then, as illustrated in FIG. 8D, the opening portion 13 is formed in the Si substrate 10a through etching. The membrane-structure displacement portion 12 is formed as a result.

### Working Example 3

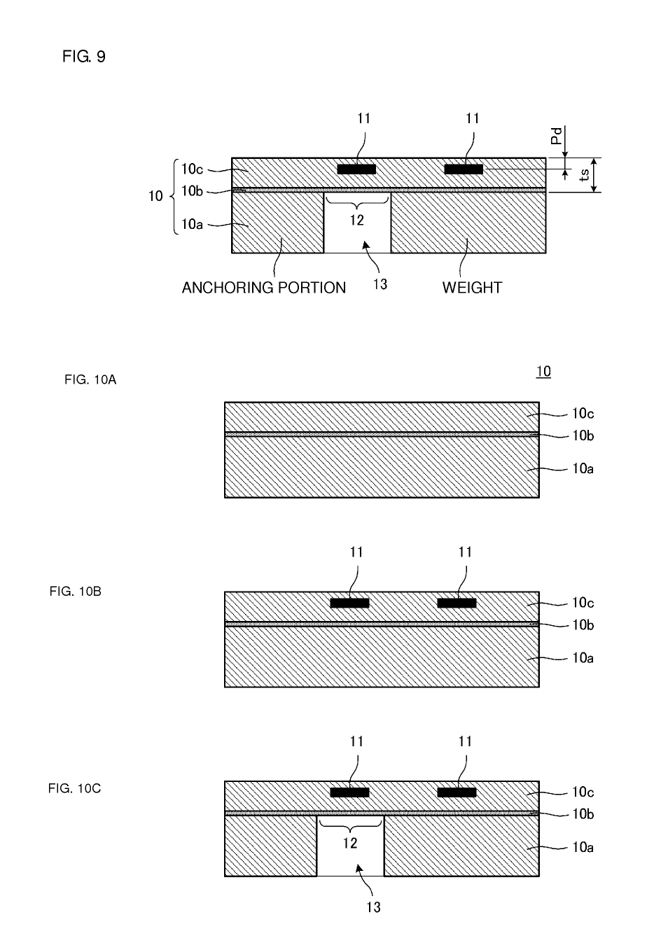

FIG. 9 is a cross-sectional view of an accelerometer according to Working Example 3. This accelerometer includes a SOI substrate that includes the Si substrate 10a, the SiO₂ layer 10b, and the surface Si film 10c. The opening portion 13 is formed in the Si substrate 10a preferably through etching, and the displacement portion 12 having a beam structure is defined by the surface Si film 10c and the SiO₂ layer 10b in this area. One side of the Si substrate 10a connected by the beam-structure displacement portion 12 defines and functions as an anchoring portion, and the other side of the Si substrate 10a acts as a weight. The piezoresistive element 11 is formed in the displacement portion 12 preferably through ion injection. The displacement portion 12 bends in response to an acceleration to be detected and a resistance value of the piezoresistive element changes in response thereto.

Here, the thickness dimension is of the membrane-structure displacement portion 12 preferably is not less than about 1 μm and not greater than about 10 μm, and the position (depth) Pd of the peak of the impurity concentration of the piezoresistive element 11 preferably is greater than about 0.5 μm and at a position less than about ½ of the depth of the thickness dimension of the displacement portion 12, for example.

FIG. 10A, FIG. 10B, and FIG. 10C are cross-sectional views illustrating a non-limiting example of a process for manufacturing the accelerometer illustrated in FIG. 9. First, as illustrated in FIG. 10A, the SOI substrate 10 formed of the Si substrate 10a, the SiO₂ layer 10b, and the surface Si film 10c is prepared. Next, as illustrated in FIG. 10B, the piezoresistive element 11 is formed through ion injection from the surface Si film 10c. Then, as illustrated in FIG. 10C, the opening portion 13 is formed in the Si substrate 10a through etching. The beam-structure displacement portion 12 is formed as a result.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. A piezoresistive MEMS sensor, comprising:
a displacement portion defined by Si with a thickness of not less than about 1 μm and configured to be displaced according to a detection amount; and
a piezoresistive element including an impurity diffused material within the displacement portion; wherein
the piezoresistive element has an impurity concentration peak at a position deeper than about 0.5 μm from a surface of the displacement portion and shallower than about ½ of a thickness of the displacement portion.

3. The piezoresistive MEMS sensor according to claim 2, wherein the thickness of the displacement portion is not less than about 1 μm and not greater than about 10 μm.

4. The piezoresistive MEMS sensor according to claim 2, wherein a Si oxide film or a Si nitride film is located on a surface of the displacement portion.

5. The piezoresistive MEMS sensor according to claim 2, wherein the piezoresistive MEMS sensor is a pressure sensor.

6. The piezoresistive MEMS sensor according to claim 2, further comprising an SOI substrate including a Si substrate, a SiO₂ layer, and a surface Si film.

7. The piezoresistive MEMS sensor according to claim 6, wherein the Si substrate includes an opening.

8. The piezoresistive MEMS sensor according to claim 6, wherein the displacement portion has a membrane structure.

9. The piezoresistive MEMS sensor according to claim 8, wherein the thickness of the displacement portion is not greater than about 10 μm.

10. The piezoresistive MEMS sensor according to claim 6, further comprising a protective film provided on the Si film.

11. An accelerometer comprising the piezoresistive MEMS sensor according to claim 2.

12. The accelerometer according to claim 11, further comprising an SOI substrate including a Si substrate, a SiO₂ layer, and a surface Si film.

13. The accelerometer according to claim 12, wherein the Si substrate includes an opening.

14. The accelerometer according to claim 11, wherein the displacement portion has a beam structure.

15. The accelerometer according to claim 11, wherein the thickness of the displacement portion is not greater than about 10 μm.
